(19) United States
(12) Patent Application Publication
(10) Pub. No.: US 2026/0173435 A1
(43) Pub. Date: Jun. 18, 2026

(54) LINED SOURCE/DRAIN REGIONS IN INTEGRATED CIRCUIT STRUCTURES

(71) Applicant: Intel Corporation, Santa Clara, CA (US)

(72) Inventors: Chun Wing Yeung, Portland, OR (US); Tao Chu, Portland, OR (US); Guowei Xu, Portland, OR (US); Robin Chao, Portland, OR (US); Lin Hu, Portland, OR (US); Feng Zhang, Portland, OR (US); Ting-Hsiang Hung, Beaverton, OR (US); Chia-Ching Lin, Portland, OR (US); Yang Zhang, Rio Rancho, NM (US); Kan Zhang, Hillsboro, OR (US); Minwoo Jang, Portland, OR (US); Yanbin Luo, Portland, OR (US); Paul Packan, Hillsboro, OR (US); Chung-Hsun Lin, Portland, OR (US); Tahir Ghani, Portland, OR (US); Glenn A. Glass, Portland, OR (US); Qianying Ku, Portland, OR (US); Jae Hur, Hillsboro, OR (US)

(73) Assignee: Intel Corporation, Santa Clara, CA (US)

(21) Appl. No.: 18/978,371

(22) Filed: Dec. 12, 2024

(51) Int. Cl. H10D 30/00; H10D 30/01

(52) U.S. Cl. CPC H10D 30/502; H10D 30/0191; H10D 30/0195; H10D 30/507

(57) ABSTRACT

Integrated circuit (IC) structures with lined source or drain regions, as well as related method and devices, are disclosed. In one aspect, an IC structure may include a channel region of a transistor, a first region proximate to a first end of the channel region, and a second region proximate to a second end of the channel region, wherein one of the first region and the second region is a source region of the transistor and another one of the first region and the second region is a drain region of the transistor, the first region includes a liner material and a fill material, the liner material is laterally between the fill material and the channel region, and a material composition of the liner material is different from a material composition of the fill material.

### BACKGROUND

For the past several decades, the scaling of features in integrated circuit (IC) structures has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize every portion of an IC structure becomes increasingly significant.

Source and drain regions of a transistor, specifically in a field-effect transistor (FET) like a metal-oxide-semiconductor field-effect transistor (MOSFET), are two of the key terminals that play a crucial role in the transistor's operation. A source region is the region from which charge carriers (electrons or holes) are supplied to the channel of the transistor. A drain region is the region where the charge carriers exit the channel. As is common in the field of FETs, designations of source and drain are often interchangeable and, therefore, source and drain regions may be referred to as a first source/drain (S/D) region and a second S/D region, where one of the first and second S/D regions is a source region, and the other one is a drain region.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a perspective view of an example nanoribbon-based FET, according to some embodiments of the present disclosure.

FIG. 2A is a flow diagram of an example method of fabricating an IC structure with lined S/D regions for the example of nanoribbon transistors, in accordance with some embodiments.

FIG. 2B is a flow diagram of an example method of fabricating an IC structure with lined S/D regions independent of transistor architecture, in accordance with some embodiments.

FIG. 3, FIG. 4, FIG. 5, FIGS. 6A-6C, FIGS. 7A-7C, FIGS. 8A-8C, and FIGS. 9A-9C provide cross-sectional side views at various stages in the fabrication of an example IC structure according to the method of FIG. 2A, in accordance with some embodiments.

FIG. 10 is a top view of a wafer and dies that may include any of the IC structures disclosed herein, in accordance with any of the embodiments disclosed herein.

FIG. 11 is a side, cross-sectional view of an IC device that may include any of the IC structures disclosed herein, in accordance with any of the embodiments disclosed herein.

FIG. 12 is a side, cross-sectional view of an IC package that may include any of the IC structures disclosed herein, in accordance with various embodiments.

FIG. 13 is a side, cross-sectional view of an IC device assembly that may include any of the IC structures disclosed herein, in accordance with any of the embodiments disclosed herein.

FIG. 14 is a block diagram of an example electrical device that may include any of the IC structures disclosed herein, in accordance with any of the embodiments disclosed herein.

### DETAILED DESCRIPTION

Disclosed herein are IC structures with lined S/D regions, as well as related methods and devices. The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

For purposes of illustrating IC structures with lined S/D regions, proposed herein, it might be useful to first understand phenomena that may come into play in IC fabrication. The following foundational information may be viewed as a basis from which the present disclosure may be properly explained. Such information is offered for purposes of explanation only and, accordingly, should not be construed in any way to limit the broad scope of the present disclosure and its potential applications.

A FET, e.g., a MOSFET, is a three-terminal device that includes source, drain, and gate terminals and uses electric field to control current flowing through the device. A FET typically includes a semiconductor material forming a channel portion of a transistor, a source region and a drain region provided on either side of the channel portion, and a gate stack that includes at least a gate electrode material and, optionally, may also include a gate insulator, where the gate stack is provided over at least a portion of the channel portion between the source region and the drain region.

Recently, FETs with non-planar architectures, such as nanoribbon transistors (also sometimes referred to as “gate all-around (GAA) transistors”), have been extensively explored as alternatives to transistors with planar architectures. In a nanoribbon transistor, a gate stack may be provided around a portion of an elongated semiconductor structure called “nanoribbon”, forming a gate on all sides of the nanoribbon. The “channel” or the “channel portion” of a nanoribbon transistor is the portion of the nanoribbon around which the gate stack wraps. Such transistors are sometimes referred to as “GAA transistors” because, in use, such transistors may form conducting channels on all “sides” of the channel portion of the nanoribbon. A source region and a drain region are provided in the nanoribbon on each side of the gate stack, forming, respectively, a source and a drain of a nanoribbon transistor. In some settings, the terms “nanoribbon” or “nanosheet” have been used to describe an elongated semiconductor structure that has a substantially rectangular transverse cross-section (i.e., a cross-section in a plane perpendicular to the longitudinal axis of the structure), while the term “nanowire” has been used to describe a similar structure but with a substantially circular or square transverse cross-sections. In the present disclosure, the term “nanoribbon” is used to refer to all such nanowires, nanoribbons, and nanosheets, as well as elongated semiconductor structures with a longitudinal axis parallel to the bases and with having transverse cross-sections of any geometry (e.g., transverse cross-sections in the shape of an oval or a polygon with rounded corners). A transistor may then be described as a “nanoribbon transistor” if the channel of the transistor is a portion of a nanoribbon, i.e., a portion around which a gate stack of a transistor may wrap around. The semiconductor material in the portion of the nanoribbon that forms a channel of a transistor may be referred to as a “channel material,” with S/D regions of a transistor provided on either side of the channel material. In some implementations, a nanoribbon transistor may include a stack of nanoribbons, where the stack includes two or more nanoribbons stacked above one another, with a single gate stack that includes a gate electrode material (which may include a work function material) provided for the entire stack.

Typically, nanoribbon transistor arrangements include stacks of nanoribbons, where each stack includes two or more nanoribbons stacked above one another, with a single gate stack that includes a gate electrode material provided for an entire stack or multiple stacks. Optionally, the gate stack may also include a gate dielectric material around one or more channel regions of each nanoribbon. According to conventional fabrication approaches, such nanoribbon transistor arrangements may be fabricated by, first, providing a stack of alternating layers of first and second semiconductor materials over a base (e.g., a substrate, a die, a wafer, or a chip). The first semiconductor material is a material that will later form nanoribbons, while the second semiconductor material is a material that is etch-selective with respect to the first semiconductor material so that it may later be removed to separate different nanoribbons of a stack from one another. For example, the first semiconductor material may be silicon, while the second semiconductor material may be silicon germanium. In such a fabrication process, the first semiconductor material provides the bottom layer of the stack as well two or more layers above the bottom layer, alternating with layers of the second semiconductor material. A stack of first and second semiconductor materials alternating with one another is referred to as a “superlattice”. The fabrication process further includes patterning the superlattice, as well as, possibly, an upper portion of the base into a fin to define the width of future nanoribbons. Sidewalls of a bottom portion of the fin are enclosed by an insulator material commonly referred to as a “shallow trench insulator” (STI) and such a bottom portion of the fin enclosed by the STI is commonly referred to as a “subfin,” similar to a subfin portion of fin-based transistors. The subfin may include the bottom layer of the first semiconductor material of the superlattice and an upper portion of the base over which the superlattice was provided. The fabrication process further includes removing the second semiconductor material from the fin to release nanoribbons formed by the fin portions of the first semiconductor material above the subfin (a process sometimes referred to as a “nanoribbon release”). After the nanoribbons are released, a gate stack may be provided around portions of the nanoribbons formed of the higher levels of the first semiconductor material, while the first semiconductor material in the subfin portion of the fin may remain but does not serve as a part of the nanoribbon transistors.

Conventionally, S/D regions of a future transistor are fabricated prior to nanoribbon release (e.g., fabricated once the fin has been formed and before the second semiconductor material is removed from the fin to release nanoribbons). Embodiments of the present disclosure are based on recognition that etch processes used to perform the nanoribbon release may negatively affect the S/D regions, compromising transistor performance, and even cause undesired shorts between S/D contacts and a gate of the transistor. Embodiments of the present disclosure are further based on recognition that lining S/D regions of a transistor with certain liner materials (e.g., depositing thin layers of liner materials into openings of future S/D regions prior to depositing the fill material of the S/D regions) may alleviate these potential issues. In one aspect, an IC structure may include a channel region of a transistor, a first region proximate to a first end of the channel region, and a second region proximate to a second end of the channel region, wherein one of the first region and the second region is a source region of the transistor and another one of the first region and the second region is a drain region of the transistor, the first region includes a liner material and a fill material, the liner material is laterally between the fill material and the channel region, and a material composition of the liner material is different from a material composition of the fill material. Such a first region may then be referred to as a “lined S/D region.” Including carefully selected liner materials in S/D regions of transistors may help protect the S/D regions from subsequent etch processes, e.g., those used to perform a nanoribbon release or those used during gate metallization.

IC structures with lined S/D regions (e.g., nanoribbon transistors with S/D regions as described herein), may be included in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency (RF) IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations.

In the following detailed description, various aspects of the illustrative implementations may be described using terms commonly employed by those skilled in the art to convey the substance of their work to others skilled in the art. For example, in context of S/D contacts of a transistor, the term “contact” may be used interchangeably with the term “terminal” of a transistor. In another example, as used herein, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” “sulfide,” etc. refer to compounds containing, respectively, oxygen, carbon, nitrogen, sulfur, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−20%, e.g., within +/−5% or within +/−2%, of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

Although certain elements may be referred to in the singular herein, such elements may include multiple sub-elements. For example, “an insulator material” may include one or more insulator materials. The term “insulating” and variations thereof (e.g., “insulative” or “insulator”) means “electrically insulating,” the term “conducting” and variations thereof (e.g., “conductive” or “conductor”) means “electrically conducting,” unless otherwise specified. For example, the term “insulator material” may refer to solid materials (and/or liquid materials that solidify after processing as described herein) that are substantially electrically non-conducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. With reference to optical signals and/or devices, components and elements that operate on or using optical signals, the term “conducting/conductive” can also mean “optically conducting/conductive.”

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

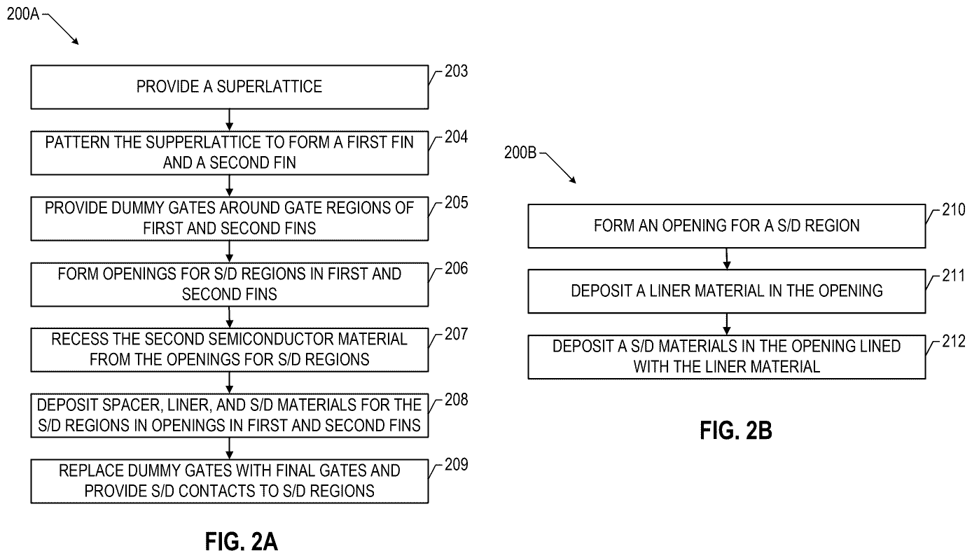

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. To not clutter the drawings, if multiple instances of certain elements are illustrated, only some of the elements may be labeled with a reference sign. A plurality of drawings with the same number and different letters may be referred to without the letters, e.g., FIGS. 2A-2B may be referred to as “FIG. 2.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using, e.g., optical microscopy, TEM, or SEM, and/or inspection of a cross-section of a device to detect the shape and the location of various device elements described herein using, e.g., Physical Failure Analysis (PFA) would allow determination of presence of IC structures with lined S/D regions.

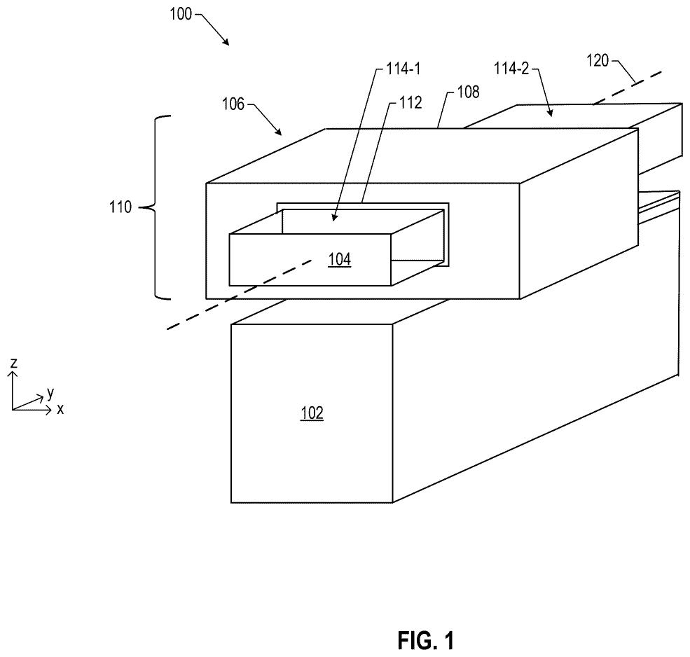

FIG. 1 provides a perspective view of an example IC structure 100 with a nanoribbon transistor 110, according to some embodiments of the present disclosure. As shown in FIG. 1, the IC structure 100 includes a semiconductor material formed as a nanoribbon 104 extending substantially parallel to a base 102. The transistor 110 may be formed on the basis of the nanoribbon 104 by having a gate stack 106 wrap around at least a portion of the nanoribbon referred to as a “channel portion” and by having source and drain regions, shown in FIG. 1 as a first S/D region 114-1 and a second S/D region 114-2 (together referred to as “S/D regions 114”), on either side of the gate stack 106. One of the S/D regions 114 is a source region and the other one is a drain region. However, because, as is common in the field of FETs, designations of source and drain are often interchangeable, they are simply referred to herein as a first S/D region 114-1 and a second S/D region 114-2.

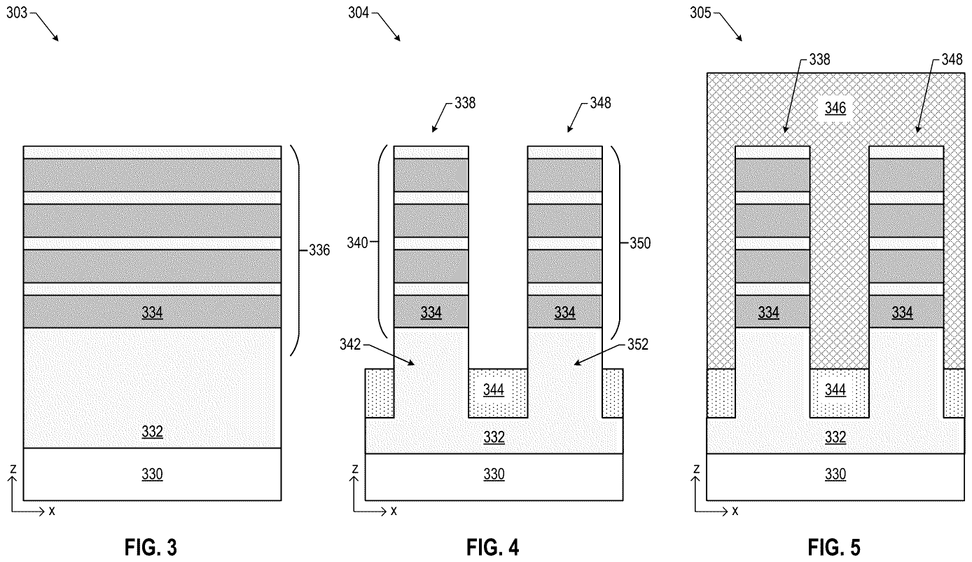

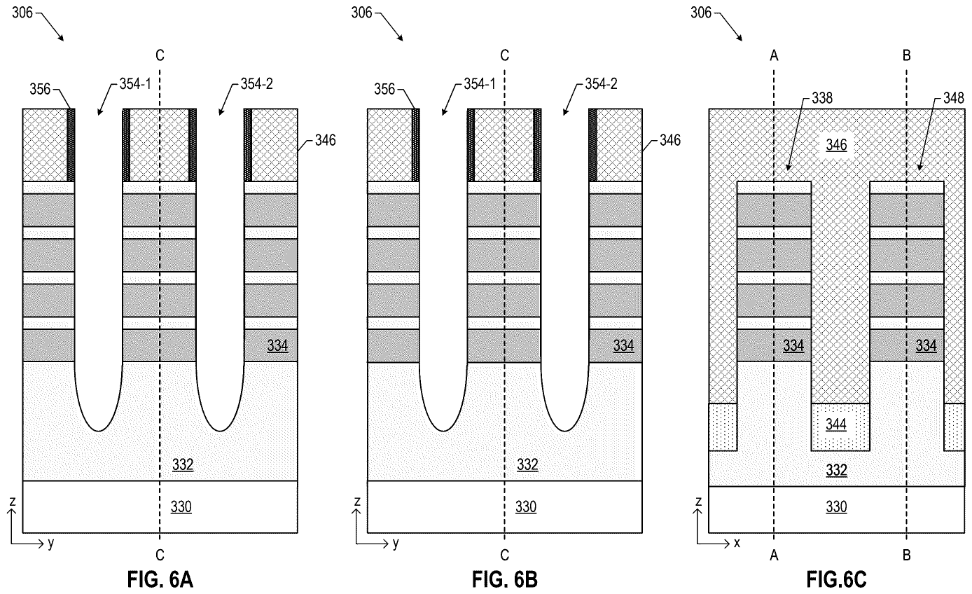

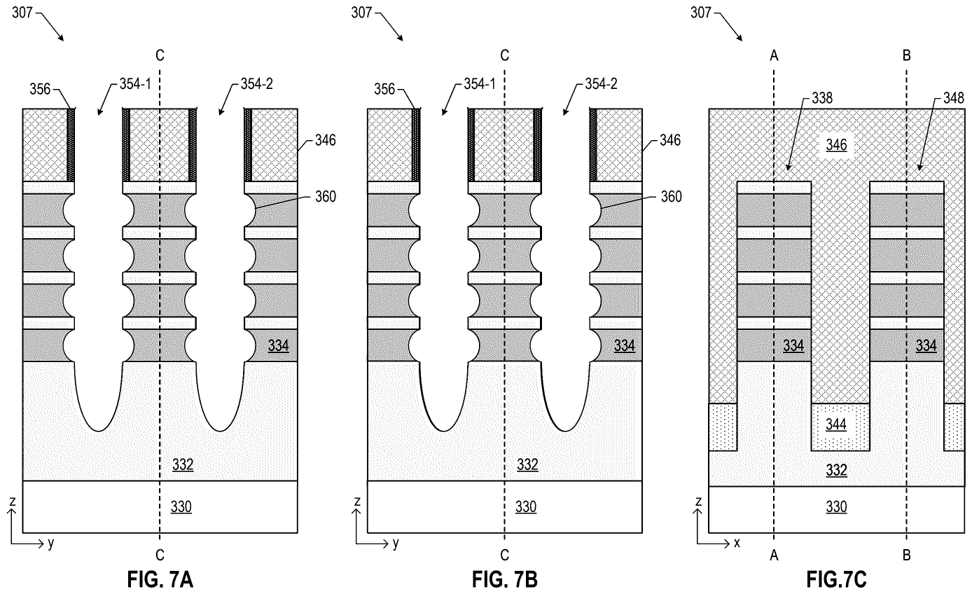

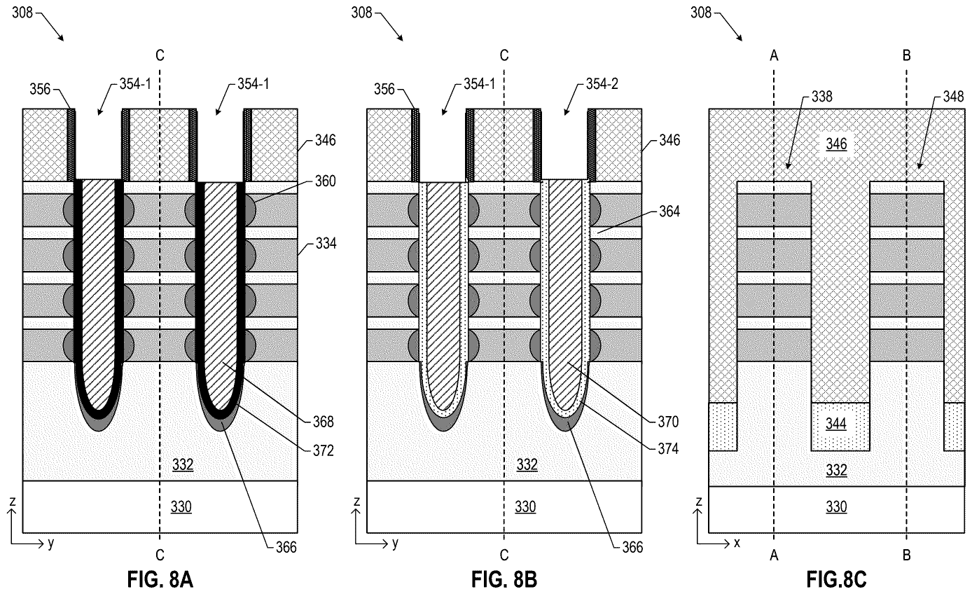

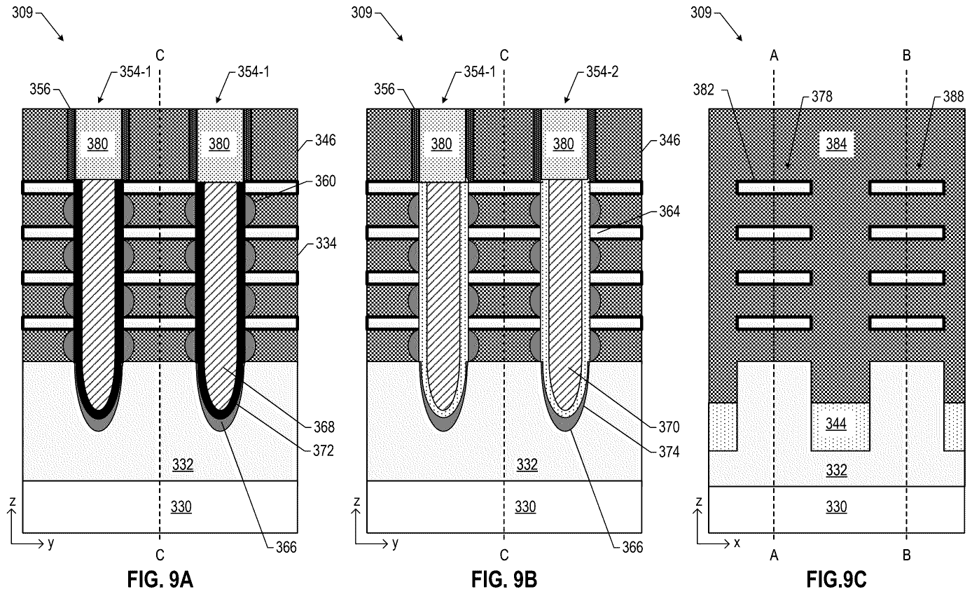

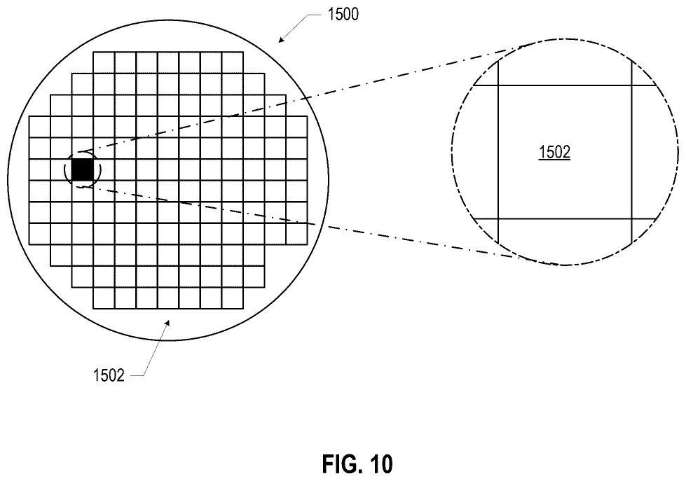

Implementations of the present disclosure may be formed or carried out on any suitable base 102, such as a substrate, a die, a wafer, or a chip. The base 102 may, e.g., be the wafer 1500 of FIG. 10, discussed below, and may be, or be included in, a die, e.g., the singulated die 1502 of FIG. 10, discussed below. The base 102 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the base 102 may be a printed circuit board (PCB) substrate, a package substrate, an interposer, a wafer, or a die. Although a few examples of materials from which the base 102 may be formed are described here, any material that may serve as a foundation upon which an IC structure with lined S/D regions as described herein may be built falls within the spirit and scope of the present disclosure. Although only one nanoribbon 104 is shown in FIG. 1, the IC structure 100 may include a stack of such nanoribbons where a plurality of nanoribbons 104 are stacked above one another, e.g., as is shown in FIGS. 3-9 showing IC structures that may be examples of the IC structure 100. In some embodiments, a portion of the base 102 right below the lowest nanoribbon 104 of the stack may be shaped as a subfin extending away from a base, as is known in the field of nanoribbon transistors.

The nanoribbon 104 may take the form of a nanowire or nanoribbon, for example. In some embodiments, an area of a transversal cross-section of the nanoribbon 104 (i.e., an area in the x-z plane of the example coordinate system x-y-z shown in FIG. 1, perpendicular to a longitudinal axis 120 of the nanoribbon 104) may be between about 25 and 10000 square nanometers, including all values and ranges therein (e.g., between about 25 and 1000 square nanometers, or between about 25 and 500 square nanometers). In some embodiments, a width of the nanoribbon 104 (i.e., a dimension measured in a plane parallel to the base 102 and in a direction perpendicular to the longitudinal axis 120 of the nanoribbon 104, e.g., along the y-axis of the example coordinate system shown in FIG. 1) may be at least about 3 times larger than a height of the nanoribbon 104 (i.e., a dimension measured in a plane perpendicular to the base 102, e.g., along the z-axis of the example coordinate system shown in FIG. 1), including all values and ranges therein, e.g., at least about 4 times larger, or at least about 5 times larger. Although the nanoribbon 104 illustrated in FIG. 1 is shown as having a rectangular cross-section, the nanoribbon 104 may instead have a cross-section that is rounded at corners or otherwise irregularly shaped, and the gate stack 106 may conform to the shape of the nanoribbon 104. The term “face” of a nanoribbon may refer to the side of the nanoribbon 104 that is larger than the side perpendicular to it (when measured in a plane substantially perpendicular to the longitudinal axis 120 of the nanoribbon 104), the latter side being referred to as a “sidewall” of a nanoribbon.

In various embodiments, the semiconductor material of the nanoribbon 104 may be composed of semiconductor material systems including, for example, N-type or P-type materials systems. In some embodiments, the nanoribbon 104 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the nanoribbon 104 may include a combination of semiconductor materials. In some embodiments, the nanoribbon 104 may include a monocrystalline semiconductor, such as silicon (Si) or germanium (Ge). In some embodiments, the nanoribbon 104 may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (i.e., for the embodiments where the transistor 110 is an NMOS transistor), the channel material of the nanoribbon 104 may include a III-V material having a relatively high electron mobility, such as, but not limited to InGaAs, InP, InSb, and InAs. For some such embodiments, the channel material of the nanoribbon 104 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where the transistor 110 is a PMOS transistor), the channel material of the nanoribbon 104 may advantageously be a group IV material having a high hole mobility, such as, but not limited to Ge or a Ge-rich SiGe alloy. For some example embodiments, the channel material of the nanoribbon 104 may have a Ge content between 0.6 and 0.9, and advantageously may be at least 0.7.

In some embodiments, the channel material of the nanoribbon 104 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if the transistor formed in the nanoribbon is a thin-film transistor (TFT), the channel material of the nanoribbon 104 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material of the nanoribbon 104 may have a thickness between about 5 and 75 nanometers, including all values and ranges therein. In some embodiments, a thin-film channel material may be deposited at relatively low temperatures, which allows depositing the channel material within the thermal budgets imposed on back end fabrication to avoid damaging other components, e.g., front end components such as the logic devices.

A gate stack 106 including a gate electrode 108 and, optionally, a gate insulator 112, may wrap entirely or almost entirely around a portion of the nanoribbon 104 as shown in FIG. 1, with the active region (channel region) of the channel material of the transistor 110 corresponding to the portion of the nanoribbon 104 wrapped by the gate stack 106. As shown in FIG. 1, the gate insulator 112 may wrap around a transversal portion of the nanoribbon 104 and the gate electrode 108 may wrap around the gate insulator 112.

The gate electrode 108 may include at least one P-type work function metal or N-type work function metal, depending on whether the transistor of which it is a part is to be a PMOS or an NMOS transistor. For example, a P-type work function metal may be used as the gate electrode 108 when the transistor 110 is a PMOS transistor and an N-type work function metal may be used as the gate electrode 108 when the transistor 110 is an NMOS transistor. For a PMOS transistor, metals that may be used for the gate electrode 108 may include, but are not limited to, ruthenium, palladium, platinum, cobalt, nickel, and conductive metal oxides (e.g., ruthenium oxide). For an NMOS transistor, metals that may be used for the gate electrode 108 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 108 may include a stack of two or more metal layers, where one or more metal layers are work function metal layers and at least one metal layer is a fill metal layer. Further metal layers may be included for other purposes, such as a barrier layer (e.g., tantalum, tantalum nitride, an aluminum-containing alloy, etc.). In some embodiments, a gate electrode 108 may include a resistance-reducing cap layer (e.g., copper, gold, cobalt, or tungsten). Further layers may be included next to the gate electrode 108 for other purposes, such as to act as a diffusion barrier layer or/and an adhesion layer.

In some embodiments, the gate insulator 112 may include one or more high-k dielectrics including any of the materials discussed herein with reference to the insulator material that may surround portions of the transistor 110. In some embodiments, an annealing process may be carried out on the gate insulator 112 during fabricate of the transistor 110 to improve the quality of the gate insulator 112. The gate insulator 112 may have a thickness that may, in some embodiments, be between about 0.5 nanometers and 3 nanometers, including all values and ranges therein (e.g., between about 1 and 3 nanometers, or between about 1 and 2 nanometers). In some embodiments, the gate stack 106 may be surrounded by a gate spacer, not shown in FIG. 1. Such a gate spacer would be configured to provide separation between the gate stack 106 and source/drain contacts of the transistor 110 and could be made of a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass. A gate spacer may include pores or air gaps to further reduce its dielectric constant.

In some embodiments, e.g., when the transistor 110 is a storage transistor of a hysteretic memory cell (i.e., a type of memory that functions based on the phenomenon of hysteresis), the gate insulator 112 may be replaced with, or complemented by, a hysteretic material. In some embodiments, a hysteretic material may be provided as a layer of a ferroelectric (FE) or an antiferroelectric (AFE) material. Such an FE/AFE material may include one or more materials that can exhibit sufficient FE/AFE behavior even at thin dimensions, e.g., such as an insulator material at least about 10% of which is in an orthorhombic phase or a tetragonal phase (e.g., as a material in which at most about 90% of the material may be amorphous or in a monoclinic phase). Some examples of such materials include materials that include hafnium, oxygen, and zirconium (e.g., hafnium zirconium oxide (HfZrO, also referred to as HZO)), materials that include hafnium, oxygen, and silicon (e.g., silicon-doped (Si-doped) hafnium oxide), materials that include hafnium, oxygen, and germanium (e.g., germanium-doped (Ge-doped) hafnium oxide), materials that include hafnium, oxygen, and aluminum (e.g., aluminum-doped (Al-doped) hafnium oxide), and materials that include hafnium, oxygen, and yttrium (e.g., yttrium-doped (Y-doped) hafnium oxide). However, in other embodiments, any other materials which exhibit FE/AFE behavior at thin dimensions may be used to replace, or to complement, the gate insulator 112, and are within the scope of the present disclosure. The FE/AFE material included in the gate stack 106 may have a thickness that may, in some embodiments, be between about 0.5 nanometers and 10 nanometers, including all values and ranges therein (e.g., between about 1 and 8 nanometers, or between about 0.5 and 5 nanometers). In other embodiments, a hysteretic material may be provided as a stack of materials that, together, exhibit hysteretic behavior. Such a stack may include, e.g., a stack of silicon oxide and silicon nitride. Unless specified otherwise, descriptions provided herein with respect to the gate insulator 112 are equally application to embodiments where the gate insulator 112 is replaced with, or complemented by, a hysteretic material.

Turning to the S/D regions 114 of the transistor 110, in some embodiments, the S/D regions may be highly doped, e.g., with dopant concentrations of about 10²¹ cm⁻³, in order to advantageously form Ohmic contacts with the respective S/D electrodes (not shown in FIG. 1), although these regions may also have lower dopant concentrations and may form Schottky contacts in some implementations. Irrespective of the exact doping levels, the S/D regions of a transistor are the regions having dopant concentration higher than in other regions, e.g., higher than a dopant concentration in the transistor channel (i.e., in a channel material extending between the first S/D region 114-1 and the second S/D region 114-2), and, therefore, may be referred to as “highly doped” (HD) regions. Even with doped to realize threshold voltage tuning as described herein, the channel portions of transistors typically include semiconductor materials with doping concentrations significantly smaller than those of the S/D regions 114.

The S/D regions 114 of the transistor 110 may generally be formed using either an implantation/diffusion process or an etching/deposition process. In the former process, dopants such as boron, aluminum, antimony, phosphorous, or arsenic may be ion-implanted into the nanoribbon 104 to form the source and drain regions. An annealing process that activates the dopants and causes them to diffuse further into the nanoribbon 104 may follow the ion implantation process. In the latter process, portions of the nanoribbon 104 may first be etched to form recesses at the locations of the future S/D regions 114. An epitaxial deposition process may then be carried out to fill the recesses with material that is used to fabricate the S/D regions 114. In some implementations, the S/D regions 114 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 114 may be formed using one or more alternate semiconductor materials such as germanium or a group III-V material or alloy. And in further embodiments, one or more layers of metal and/or metal alloys may be used to form the S/D regions 114. In some embodiments, a distance between the first and second S/D regions 114 (i.e., a dimension measured along the longitudinal axis 120 of the nanoribbon 104) may be between about 5 and 40 nanometers, including all values and ranges therein (e.g., between about 22 and 35 nanometers, or between about 20 and 30 nanometers).

The IC structure 100 shown in FIG. 1, as well as IC structures shown in other drawings of the present disclosure, is intended to show relative arrangements of some of the components therein, and the IC structure 100, or portions thereof, may include other components that are not illustrated (e.g., electrical contacts to the S/D regions 114 of the transistor 110, additional layers such as a spacer layer around the gate electrode of the transistor 110, etc.). For example, although not specifically illustrated in FIG. 1, a dielectric spacer may be provided between a first S/D electrode (which may also be referred to as a “first S/D contact”) coupled to a first S/D region 114-1 of the transistor 110 and the gate stack 106 as well as between a second S/D electrode (which may also be referred to as a “second S/D contact”) coupled to a second S/D region 114-2 of the transistor 110 and the gate stack 106 in order to provide electrical isolation between the source, gate, and drain electrodes. In another example, although not specifically illustrated in FIG. 1, at least portions of the transistor 110 may be surrounded in an insulator material, such as any suitable interlayer dielectric (ILD) material. In some embodiments, such an insulator material may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material surrounding portions of the transistor 110 may be a low-k dielectric material.

FIG. 2A is a flow diagram of an example method 200A of fabricating an IC structure with lined S/D regions for the example of nanoribbon transistors, in accordance with some embodiments, and FIG. 2B is a flow diagram of an example method 200B of fabricating an IC structure with lined S/D regions independent of transistor architecture, in accordance with some embodiments. Although the operations of the methods 200A and 200B are illustrated once each and in a particular order, the operations may be performed in any suitable order and repeated as desired. For example, one or more operations may be performed in parallel to fabricate multiple IC structures with nanoribbon transistors substantially simultaneously. In another example, the operations of the methods 200A and 200B may be performed in a different order than what is shown. In addition, the example fabricating methods 200A and 200B may include other operations not specifically shown in FIGS. 2A and 2B, such as various cleaning or planarization operations as known in the art. For example, in some embodiments, the base 102, as well as layers of various other materials subsequently deposited thereon, may be cleaned prior to, after, or during any of the processes of the methods 200A and 200B described herein, e.g., to remove oxides, surface-bound organic and metallic contaminants, as well as subsurface contamination. In some embodiments, cleaning may be carried out using e.g., a chemical solution (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the methods 200A and 200B described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

FIGS. 3-9 provide cross-sectional side views at various stages in the fabrication of an example IC structure according to the method 200A of FIG. 2A, in accordance with some embodiments. Some of FIGS. 3-9 (e.g., FIGS. 6-9) includes three figures, labeled with letters A, B, and C (e.g., FIG. 6 includes FIGS. 6A, 6B, and 6C), providing different cross-sectional side views of a given IC structure. In particular, those figures of FIGS. 3-9 that are labeled with a letter A (e.g., FIG. 6A, FIG. 7A, FIG. 8A, and FIG. 9A) illustrate cross-sections in the y-z plane of the example coordinate system shown in FIG. 1 along a plane AA shown in a corresponding figure labeled with a letter C (e.g., along a plane AA shown in FIG. 6C). Those figures of FIGS. 3-9 that are labeled with a letter B (e.g., FIG. 6B, FIG. 7B, FIG. 8B, and FIG. 9B) illustrate cross-sections in the y-z plane of the example coordinate system shown in FIG. 1 along a plane BB shown in a corresponding figure labeled with a letter C (e.g., along a plane BB shown in FIG. 6C). Those figures of FIGS. 3-9 that are labeled with a letter C (e.g., FIG. 6C, FIG. 7C, FIG. 8C, and FIG. 9C) illustrate cross-sections in the x-z plane of the example coordinate system shown in FIG. 1 along a plane CC shown in FIG. 6A and FIG. 6B. In order to not clutter the drawings, planes AA, BB, and CC may not be shown in some of FIGS. 3-9. Those of FIGS. 3-9 that only show one cross-section (e.g., FIGS. 3-5), illustrate a cross-section in the x-z plane of the example coordinate system shown in FIG. 1 (i.e., those figures are similar to figures labeled with a letter C).

The method 200A may begin with a process 203 that includes providing a superlattice of first and second semiconductor materials over a base. An IC structure 303 of FIG. 3 illustrates an example result of the process 203. The IC structure 303 includes a base 330 with a first semiconductor material 332 over the base 330. The base 330 may be a base 102 described above. The first semiconductor material 332 may either be a layer of a semiconductor material deposited over the base 330, or the first semiconductor material 332 may be an upper part of the base 330. FIG. 3 further illustrates a second semiconductor material 334 deposited over the first semiconductor material 332, after which the first semiconductor material 332 and the second semiconductor material 334 are deposited in alternation. As shown in FIG. 3, the IC structure 303 may include a superlattice 336 of alternating layers of the first semiconductor material 332 and the second semiconductor material 334. In some embodiments, the superlattice 336 may start with the first semiconductor material 332 (i.e., the first semiconductor material 332 may be the bottom layer of the superlattice 336), as shown in FIG. 3; however, in other embodiments, the superlattice 336 may start with the second semiconductor material 334 instead. In some embodiments, the superlattice 336 may end with the first semiconductor material 332 (i.e., the first semiconductor material 332 may be the uppermost layer of the superlattice 336), as shown in FIG. 3; however, in other embodiments, the superlattice 336 may end with the second semiconductor material 334 instead. The first semiconductor material 332 may include any of the materials described with reference to the nanoribbon 104. The first semiconductor material 332 and the second semiconductor material 334 may be any semiconductor materials that are sufficiently etch-selective with respect to one another. For example, the first semiconductor material 332 may be silicon and the second semiconductor material 334 may be silicon germanium.

FIG. 3 illustrates a total of five layers of the first semiconductor material 332 and a four layers of the second semiconductor material 334, in an alternating manner, but, in other embodiments, the superlattice 336 may include any other number of one or more pairs of a layer of the first semiconductor material 332 and a layer of 334. Furthermore, FIG. 3 illustrates that the layers of the first semiconductor material 332 are thinner than the layers of the second semiconductor material 334, the thickness being measured along the z-axis of the example coordinate system shown. However, this may not be the case in other embodiments, where the second semiconductor material 334 may be thinner than the first semiconductor material 332, and/or any of the layers of the first semiconductor material 332 and the second semiconductor material 334 within the superlattice 336 may have any suitable thickness that may be different from other layers. In some embodiments, any of the layers of the first semiconductor material 332 or of the second semiconductor material 334 may have a thickness between about 2 and 500 nanometers, including all values and ranges therein (e.g., between about 5 and 100 nanometers, or between about 5 and 50 nanometers). Any suitable deposition methods for depositing semiconductor materials may be used in the process 203 to deposit alternating layers of the first semiconductor material 332 and the second semiconductor material 334, such as epitaxial deposition, thin-film deposition techniques, etc.

In a process 204 of the method 200A, the superlattice provided in the process 203 may be patterned to form first and second fins that are such that one of the fins is an NMOS fin (i.e., a fin based on which NMOS nanoribbon transistors will be formed) and another one is a PMOS fin (i.e., a fin based on which PMOS nanoribbon transistors will be formed). An IC structure 304 of FIG. 4 illustrates an example result of the process 204. As shown in FIG. 4, the IC structure 304 includes a first fin 338 formed from a first portion of the superlattice 336, and a second fin 348 formed from a second portion of the superlattice 336. In the following, it may be assumed that the fin 338 is an NMOS fin and the fin 348 is a PMOS fin. The first fin 338 may include an active portion 340 and a subfin portion 342, while the second fin 348 may include an active portion 350 and a subfin portion 352. The active portions 340, 350, may be portions of the fins 338, 348 from which later the respective nanoribbons will be formed, while the subfin portions 350, 352 are portions of the fins 338, 348 that have sidewalls at least partially enclosed with an insulator material 344, e.g., as shown in FIG. 4. The insulator material 344 may include any of the insulator material typically used as STI in fin-based or nanoribbon transistors, e.g., any suitable low-k dielectric material. While FIG. 4 and subsequent drawings illustrate that the fins 338, 348 extend away from a base formed of a portion of the first semiconductor material 332, in other embodiments, the fins 338, 348 may extend further down than what is shown in the drawings, and the bottom parts of the subfin portions 342 and 352 may be in contact with or may include the base 330. In some embodiments, a distance between the fins 338 and 348 (e.g., as measured along the x-axis) may be less than about 500 nanometers, e.g., between about 10 and 300 nanometers, or between about 10 and 200 nanometers. The dimensions of the fins 338 and 348 patterned in the process 204, in particular the dimensions along the y-axis and the z-axis of the coordinate system shown, are suitable for forming NMOS and PMOS stacks of nanoribbons. For example, the dimensions of the fins 338 and 348 patterned in the process 204 may be such as to form nanoribbons with dimensions as described with reference to the nanoribbon 104 of FIG. 1. Patterning of the superlattice 336 to form the fins 338, 348 may be performed in the process 204 according to any of the known methods of forming fins. Patterning techniques that may be used in the process 204 include, but are not limited to, photolithographic or electron-beam (e-beam) patterning, possibly in conjunction with a suitable etching technique, e.g., a dry etch, such as e.g., RF reactive ion etch (RIE) or inductively coupled plasma (ICP) RIE. In some embodiments, an etch performed in the process 204 may include an anisotropic etch, using etchants in a form of e.g., chemically active ionized gas (i.e., plasma) using e.g., bromine (Br) and chloride (Cl) based chemistries. In some embodiments, during an etch of the process 204, the IC structure may be heated to elevated temperatures, e.g., to temperatures between about room temperature and 200 degrees Celsius, including all values and ranges therein, to promote that byproducts of the etch are made sufficiently volatile to be removed from the surface. The same applies for patterning steps of the method 200A.

The method 200A may then continue with a process 205 that includes defining gate regions around portions of the fins 338, 348 by providing a dummy gate 346 around portions of the fins 338, 348 that will later include channel regions of the transistors formed in the nanoribbons of the first semiconductor material 332 released from the fin 338 and in the nanoribbons released from the fin 348. An IC structure 305 of FIG. 5 illustrates an example result of the process 205. The IC structure 305 illustrates a single dummy gate 346 wrapping around active regions of both of the fins 338 and 348, although in other embodiments, the process 205 may include providing individual dummy gates 346 around the fins 338 and 348. The dummy gate 346 may include any suitable sacrificial material that will later be removed, such as polysilicon. Use of the dummy gates as part of forming gates for transistors is known in the art and, therefore, is not described herein in further detail.

The method 200A may further include a process 206 that includes forming openings for future S/D regions in the nanoribbons that will be formed from the fins 338, 348. An IC structure 306 of FIG. 6 illustrates an example result of the process 206. Because S/D regions are not seen in a gate cut cross-section of x-z plane illustrated in FIG. 5, FIG. 6 provides not only an illustration of such a gate cut, in FIG. 6C, but also an illustration of y-z plane in a cut along the fin 338, in FIG. 6A, and an illustration of y-z plane in a cut along the fin 348, in FIG. 6B. As shown in FIG. 6, the process 206 includes forming a first opening 354-1 and a second openings 354-2 (together referred to as “openings 354”) in each of the fin 338 and the fin 348. These openings in both fins may be formed substantially simultaneously. In some embodiments, portions of the openings 354 surrounded by the dummy gate 346 may be lined with a liner 356, which may include a plurality of different liners even though it is shown in FIGS. 6A and 6B and subsequent drawings as a single liner 356. The liners 356 may include one or more of spacer materials, diffusion barrier materials, adhesion materials, etc., as known in the art for forming contacts to various components of IC structures.

The method 200A may then proceed with a process 207 that includes performing a recess of the second semiconductor material 334 starting from the S/D openings formed in the process 206. An IC structure 307 of FIGS. 7A-7C illustrates an example result of the process 207. For both the fin 338 and the fin 348, the IC structure 307 illustrates that the recess is performed on the second semiconductor material 334 exposed within the openings 354. As a result, so-called “dimples” 360 may be formed in the sidewalls of the S/D openings 354 in the fin 338 and the fin 348, where the dimples 360 are areas in which the second semiconductor material 334 was recessed away from the original sidewalls of the openings 354 (i.e., recessed laterally). Any suitable etching technique may be used in the process 207 to recess the second semiconductor material 334 in the S/D openings 354, such as any suitable wet etching technique using etchants that can etch the second semiconductor material 334 without substantially etching other material of the IC structure 307. The dimples 360 may have any suitable geometry and dimensions so that, when filled with an insulator material in a later process, the dimples 360 may provide electrical insulation between the material of the S/D regions that will be within the S/D openings 354 formed in the fins 338, 348 and the gate electrode material(s) that will be present between the nanoribbons of the first semiconductor material 332 formed from the fins 338, 348. For example, a depth of the dimples 360, which is a dimension that is measured along the y-axis of the example coordinate system shown, may be between about 1 and 20 nanometers, e.g., between about 2 and 10 nanometers, or between about 3 and 7 nanometers.

The method 200A may then proceed with a process 208, which includes depositing a spacer material in the dimples 360, lining the openings 354 in the fins 338 and 348 with respective liner materials, and then filling the lined openings with S/D materials, thus forming S/D regions in the fins 338 and 348. An IC structure 308 of FIGS. 8A-8C illustrates an example result of the process 208. As shown in FIG. 8, the dimples 360 of the fin 338, as well as the dimples 364 of the fin 348 may be filled with a spacer material 366 (in some embodiments, material composition of the spacer material 366 in the dimples 360 and the dimples 364 may be the same or different). Furthermore, the spacer material 366 may also line bottoms of the openings 354 in both fins, in particular, line the subfin portions of the fins 338 and 348. As also shown in FIG. 8, sidewalls of the openings 354 are then lined with respective liner materials in the fins 338 and 348. In particular, FIG. 8A illustrates that the openings 354 in the fin 338 (i.e., the fin assumed to be the NMOS fin) are lined with a liner material 372, while the openings 354 in the fin 348 (i.e., the fin assumed to be the PMOS fin) are lined with a liner material 374. After that, remaining portions of the openings 354 within the fins 338 and 348 may be filled with respective S/D materials, shown as a S/D material 368 in the openings 354 within the fin 338 and a S/D material 370 in the openings 354 within the fin 348. The spacer material 366 may include any suitable insulator material, while the S/D materials 368, 370 may include any materials for forming S/D regions 114 of nanoribbon transistors for, respectively, NMOS and PMOS transistors. Techniques for filling S/D openings with a spacer material and S/D material during fabrication of nanoribbon transistors are known in the art and, therefore, are not described here in detail. In some embodiments, the liner materials 372, 374 may be deposited using a conformal deposition technique such as atomic layer deposition (ALD), chemical vapor deposition (CVD), plasma enhanced CVD (PECVD), or/and physical vapor deposition (PVD) processes such as sputter.

The liner material 372 and the liner material 374 may have different material compositions. For example, the liner material 372 may include silicon and germanium (e.g., the liner material 372 may include SiGe), while the liner material 374 may include silicon and boron (e.g., the liner material 374 may include SiB) and, optionally, may further include germanium (e.g., the liner material 374 may include SiB: Ge). In some embodiments, atomic percentage of germanium in the liner material 374 may be less than about 5 percent. As shown in FIG. 8, the liner materials 372, 374 may be located laterally between the respective S/D materials and the channel region of the fins 338, 348, where the liner materials 372, 374 line sidewalls and bottoms of the openings 354, and the respective S/D materials 368, 370 fill the openings 354 lined with the liner materials 372, 374. In some embodiments, a thickness of the layers of the liner materials 372, 374 may be between about 1 nanometer and 10 nanometers, e.g., smaller than about 3 nanometers. In some embodiments, a thickness of the layers of the liner materials 372, 374 may be less than about 10% of a width of the openings 354, e.g., less than about 5%. In some embodiments, the liner materials 372, 374 may be etch-selective with respect to the materials of the channel region of the NMOS and PMOS transistors (e.g., etch-selective with respect to the first semiconductor material 332). In some embodiments, the liner materials 372, 374 may be etch-selective with respect to the second semiconductor material 334, so that when nanoribbons are released in a subsequent process, the etch used to remove the second semiconductor material 334 does not substantially etch the liner materials 372, 374. In this manner, the liner materials 372, 374 may protect the S/D materials 368, 370 in the openings 354. The liner material 372 and the S/D material 368 in the openings 354-1 and 354-4 of the fin 338 will form S/D regions 114-1 and 114-2 for the NMOS transistor. Similarly, the liner material 374 and the S/D material 370 in the openings 354-1 and 354-4 of the fin 348 will form S/D regions 114-1 and 114-2 for the PMOS transistor.

The method 200A may then proceed with a process 209 that may include releasing the nanoribbons, replacing dummy gates with final gates, and providing S/D contacts to S/D regions. An IC structure 309 of FIGS. 9A-9C illustrates an example result of the process 209. The IC structure 309 illustrates that the dummy gate 346 may be removed from the gate regions of both of the fins 338, 348 in a process 209. Removal of the dummy gate 346 may include any suitable etching technique, provided the material of the dummy gate 346 is sufficiently etch-selective with respect to the other materials of the IC structure 309, in particular, with respect to the first semiconductor material 332, the second semiconductor material 334, and the insulator material 344 surrounding the subfin portions of the fins 338, 348. Next, nanoribbon release for the fins 338, 348 may be performed, where a suitable etch process may be used to remove the second semiconductor material 334 from the gate regions of the fins 338, 348 starting from the portions of the second semiconductor material 334 that are exposed by the removal of the dummy gate 346 from the fins 338, 348. As a result of removing the second semiconductor material 334 from the fin 338, a stack 378 of nanoribbons of the first semiconductor material 332 are formed for the NMOS transistor. As a result of removing the second semiconductor material 334 from the fin 348, a stack 388 of nanoribbons of the first semiconductor material 332 are formed for the PMOS transistor. Each of the nanoribbons of the stacks 378, 388 is an example of the nanoribbon 104, described above. The nanoribbons of the stacks 378, 388 are “released” in that the openings are formed around channel portions of the nanoribbons of the first semiconductor material 332, in which openings one or more of gate electrode materials such as the gate electrode 108 and, optionally, the gate insulator 112, described above, may then be deposited. FIG. 9 illustrates a gate insulator material 382 that may wrap around the gate regions of the nanoribbons of the stacks 378 and 388, as well as a gate electrode material 384. The gate insulator material 382 may take any of the embodiments of the gate insulator 112 described above. The gate electrode material 384 may take any of the embodiments of the gate electrode 108 described above. In some embodiments, the gate insulator material 382 may be absent in the IC structure 309. Furthermore, even though FIG. 9C illustrates a materially continuous gate electrode material 384 enclosing nanoribbons of both the stack 378 and the stack 388, this need not be the case. In other embodiments, a first gate electrode material may be provided for the stack 378 and a second gate electrode material may be provided for the stack 388, which gate electrode materials may be electrically insulated from one another. The IC structure 309 and all variations of such structure described herein is an example of the IC structure 100, described above. FIG. 9 further illustrates a S/D contact material 380 filling remainder of the openings 354 and making an electrical contact to the respective S/D materials 368 and 370.

Providing IC structure with S/D regions lined with the liner materials 372, 374 is not limited to nanoribbon transistors. While the method 200A of FIG. 2A was specific to nanoribbon transistors, FIG. 2B is a flow diagram of an example method 200B of fabricating an IC structure with lined S/D regions independent of transistor architecture, in accordance with some embodiments. The method 200B may begin with a process 210 that may include forming an opening for a S/D region of a future transistor. The process 210 may be similar to the process 206 of the method 200A except that it may be applicable to transistors of any architecture, such as FinFETs, planar transistors, etc. The method 200B may further include a process 211 that may include depositing a liner material in the opening formed in the process 210. The process 211 may be similar to depositing the liner materials 372, 374 in the process 208 of the method 200A except that it may be applicable to transistors of any architecture. The method 200B may conclude with a process 212 that may include depositing a S/D material in the opening lined with the liner material (i.e., in the opening resulting from the process 211). The process 212 may be similar to depositing the S/D materials 368, 370 in the process 208 of the method 200A except that it may be applicable to transistors of any architecture.

IC structures with lined S/D regions described herein (e.g., as described with reference to FIGS. 1-9) may be used to implement any suitable components. For example, in various embodiments, transistors described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a III-V amplifier), Peripheral Component Interconnect Express (PCIE) circuitry, Double Data Rate (DDR) transfer circuitry, a computing device (e.g., a wearable or a handheld computing device), etc.

The IC structures 100 disclosed herein, e.g., the IC structures 100 implemented as the IC structure 309 or any variations of the IC structure 309, may be included in any suitable electronic component. FIGS. 10-14 illustrate various examples of apparatuses that may include any of the IC structures 100 disclosed herein.

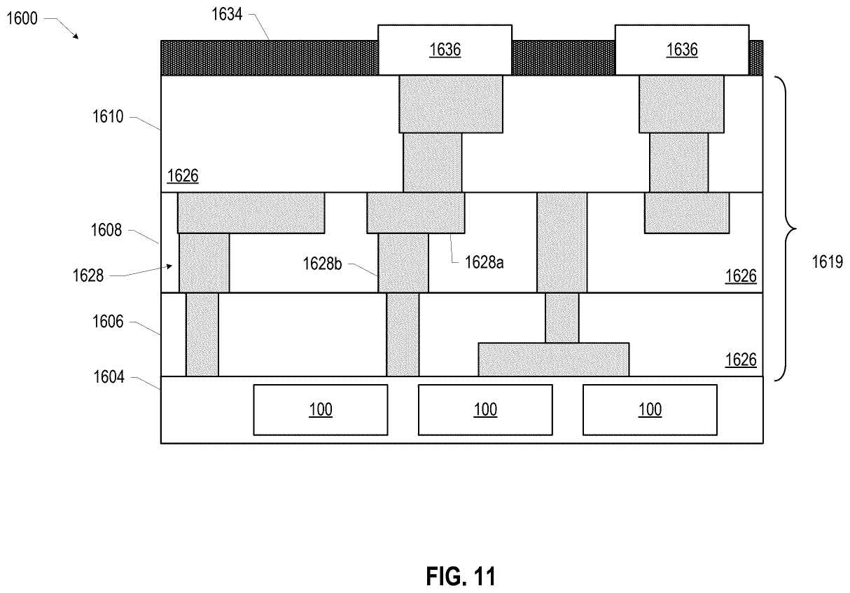

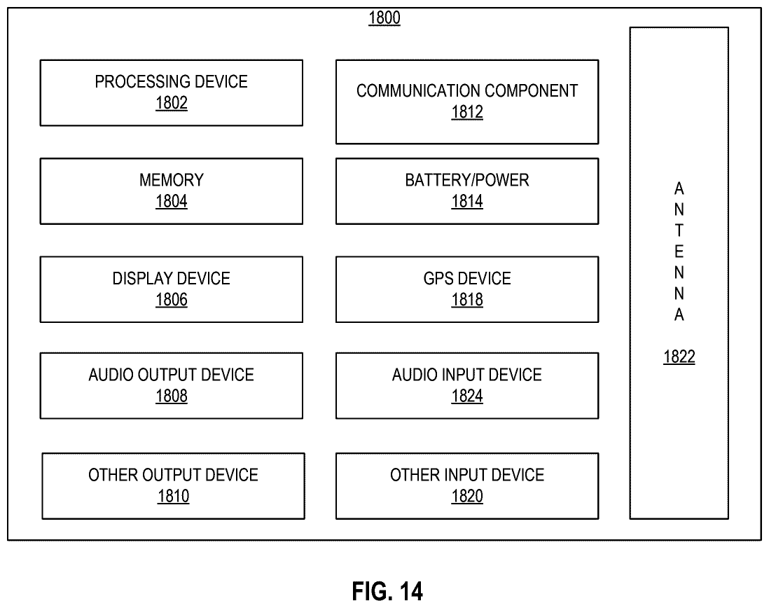

FIG. 10 is a top view of a wafer 1500 and dies 1502 that may include one or more IC structures 100 in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more IC structures 100 (e.g., as discussed below with reference to FIG. 11), one or more transistors (e.g., some of the transistors of the device region 1604 of FIG. 11, discussed below, e.g., nanoribbon transistors of the IC structures 100) and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 14) or other logic that is configured to store information in the memory devices or execute instructions stored in the memory array.

FIG. 11 is a side, cross-sectional view of an IC device 1600 that may include one or more IC structures 100 in accordance with any of the embodiments disclosed herein. One or more of the IC devices 1600 may be included in one or more dies 1502 (FIG. 10). The IC device 1600 may include a device region 1604 including one or more IC structures 100 disclosed herein, e.g., one or more of the IC structures 100 implemented as the IC structures 309 or any variations of the IC structures 309. The device region 1604 may further include electrical contacts to the gates of the transistors included in the device region 1604 and to the S/D regions of the transistors included in the device region 1604 (e.g., to the S/D regions 114 of the IC structures 100).

Electrical signals, such as power and/or input/output (I/O) signals, may be routed to and/or from the devices (e.g., the transistors) of the device region 1604 through one or more interconnect layers disposed on the device region 1604 (illustrated in FIG. 11 as interconnect layers 1606, 1608, and 1610). For example, electrically conductive features of the device region 1604 (e.g., the gate electrode 108 of the IC structures 100) may be electrically coupled with the interconnect structures 1628 of the interconnect layers 1606, 1608, and 1610. The one or more interconnect layers 1606, 1608, and 1610 may form a metallization stack (also referred to as an “ILD stack”) 1619 of the IC device 1600.

The interconnect structures 1628 may be arranged within the interconnect layers 1606, 1608, and 1610 to route electrical signals according to a wide variety of designs (in particular, the arrangement is not limited to the particular configuration of interconnect structures 1628 depicted in FIG. 11). Although a particular number of interconnect layers 1606, 1608, and 1610 is depicted in FIG. 11, embodiments of the present disclosure include IC structures having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the base 102 upon which the device region 1604 is formed. For example, the lines 1628a may route electrical signals in a direction in and out of the page from the perspective of FIG. 11. The vias 1628b may be arranged to route electrical signals in a direction of a plane that is substantially perpendicular to the surface of the base 102 upon which the device region 1604 is formed. In some embodiments, the vias 1628b may electrically couple lines 1628a of different interconnect layers 1606, 1608, and 1610 together.

The interconnect layers 1606, 1608, and 1610 may include a dielectric material 1626 disposed between the interconnect structures 1628, as shown in FIG. 11. In some embodiments, the dielectric material 1626 disposed between the interconnect structures 1628 in different ones of the interconnect layers 1606, 1608, and 1610 may have different compositions; in other embodiments, the composition of the dielectric material 1626 between different interconnect layers 1606, 1608, and 1610 may be the same.

A first interconnect layer 1606 may be formed above the device region 1604. In some embodiments, the first interconnect layer 1606 may include lines 1628a and/or vias 1628b, as shown. The lines 1628a of the first interconnect layer 1606 may be coupled with contacts (e.g., contacts to the S/D regions 114 of the IC structures 100) of the device region 1604.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device region 1604) may be thicker.

The IC device 1600 may include a solder resist material 1634 (e.g., polyimide or similar material) and one or more conductive contacts 1636 formed on the interconnect layers 1606, 1608, and 1610. In FIG. 11, the conductive contacts 1636 are illustrated as taking the form of bond pads. The conductive contacts 1636 may be electrically coupled with the interconnect structures 1628 and configured to route the electrical signals of the transistor(s) of the device region 1604 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606, 1608, and 1610; for example, the conductive contacts 1636 may include other analogous features (e.g., posts) that route the electrical signals to external components.

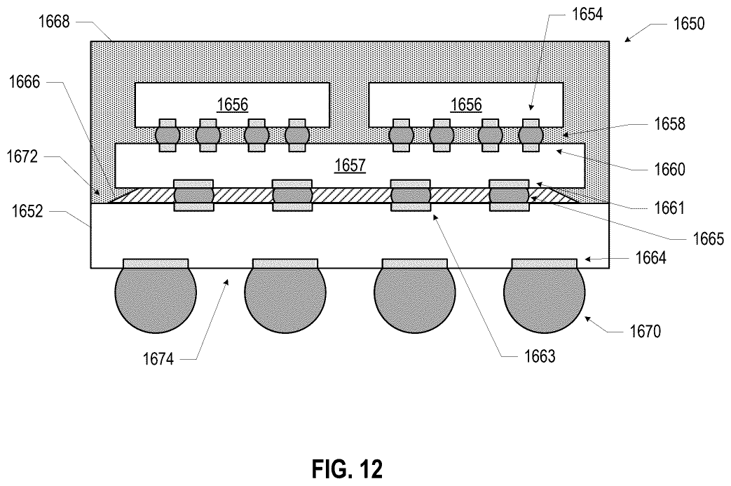

FIG. 12 is a side, cross-sectional view of an example IC package 1650 that may include one or more IC structures 100 in accordance with any of the embodiments disclosed herein. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674. These conductive pathways may take the form of any of the interconnect structures 1628 discussed above with reference to FIG. 11.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 12 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 12 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

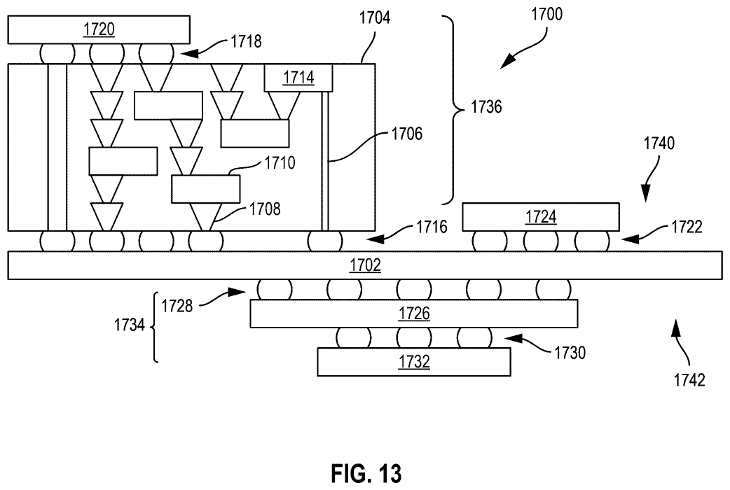

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 12 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 13.

The dies 1656 may take the form of any of the embodiments of the die 1502 discussed herein (e.g., may include any of the embodiments of the IC device 1600). In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 12 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 12, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 13 is a side, cross-sectional view of an IC device assembly 1700 that may include one or more IC packages or other electronic components (e.g., a die) including one or more IC structures 100 in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 12 (e.g., may include one or more IC structures 100).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 13 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 13), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 13, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 10), an IC device (e.g., the IC device 1600 of FIG. 11), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 13, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 13 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 14 is a block diagram of an example electrical device 1800 that may include one or more IC structures 100 in accordance with any of the embodiments disclosed herein. For example, any suitable ones of the components of the electrical device 1800 may include one or more of the IC device assemblies 1700, IC packages 1650, IC devices 1600, or dies 1502 disclosed herein. A number of components are illustrated in FIG. 14 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 14, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808 but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic RAM (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic RAM (eDRAM) or spin transfer torque magnetic RAM (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an IC structure that includes a channel region of a transistor, a first region proximate to a first end of the channel region, and a second region proximate to a second end of the channel region, in which one of the first region and the second region is a source region of the transistor and another one of the first region and the second region is a drain region of the transistor, in which: the first region includes a liner material and a fill material, the liner material is laterally between the fill material and the channel region, and a material composition of the liner material is different from a material composition of the fill material.

Example 2 provides the IC structure according to example 1, in which the liner material includes silicon and boron (e.g., the liner material includes SiB).

Example 3 provides the IC structure according to example 2, in which the liner material further includes germanium (e.g., the liner material includes SiB:Ge).

Example 4 provides the IC structure according to example 2, in which atomic percentage of germanium in the liner material is less than about 5 percent.

Example 5 provides the IC structure according to example 1, in which the liner material includes silicon and germanium (e.g., the liner material includes SiGe).

Example 6 provides the IC structure according to any one of the preceding examples, in which: the first region includes an opening in a semiconductor material of the channel region, the liner material lines sidewalls and bottom of the opening, and the fill material at least partially filles the opening lined with the liner material.

Example 7 provides the IC structure according to example 6, in which a thickness of the liner material is less than about 10% of a width of the opening.

Example 8 provides the IC structure according to any one of the preceding examples, in which a thickness of the liner material is between about 1 nanometer and 10 nanometers, e.g., smaller than about 3 nanometers.

Example 9 provides the IC structure according to any one of the preceding examples, in which a thickness of the liner material is below about 3 nanometers.

Example 10 provides the IC structure according to any one of the preceding examples, in which the liner material is etch-selective with respect to a material of the channel region.

Example 11 provides an IC structure that includes a first transistor and a second transistor, in which: an individual one of the first transistor and a second transistor includes a channel region, and a region proximate to an end of the channel region, in which the region is a source region or a drain region, the region of the first transistor includes a first liner material and a first fill material, the region of the second transistor includes a second liner material and a second fill material, the first liner material includes silicon and boron (e.g., the liner material includes SiB), and the second liner material includes silicon and germanium (e.g., the liner material includes SiGe).

Example 12 provides the IC structure according to example 11, in which the first liner material further includes germanium (e.g., the liner material includes SiB:Ge).

Example 13 provides the IC structure according to example 12, in which atomic percentage of germanium in the first liner material is less than about 5 percent.

Example 14 provides the IC structure according to any one of examples 11-13, in which: the first liner material is between the first fill material and the channel region of the first transistor, or/and the second liner material is between the second fill material and the channel region of the second transistor.

Example 15 provides the IC structure according to any one of examples 11-14, in which: a material composition of the first liner material is different from a material composition of the first fill material, or/and a material composition of the second liner material is different from a material composition of the second fill material.

Example 16 provides the IC structure according to any one of examples 11-15, in which: a material composition of the first liner material is different from a material composition of the second liner material.

Example 17 provides the IC structure according to any one of examples 11-16, in which a thickness of the first liner material is between about 1 nanometer and 10 nanometers, e.g., smaller than about 3 nanometers.

Example 18 provides the IC structure according to any one of examples 11-17, in which a thickness of the second liner material is between about 1 nanometer and 10 nanometers, e.g., smaller than about 3 nanometers.

Example 19 provides a method of fabricating an IC structure, the method including forming an opening for a region of a transistor, in which the region is either a source region or a drain region; depositing a liner material on sidewalls of the opening; and depositing a fill material in the opening with the liner material, in which: the liner material includes silicon and boron if the transistor is a P-type transistor, the liner material includes silicon and germanium if the transistor is an N-type transistor, and a material composition of the liner material is different from a material composition of the fill material.

Example 20 provides the method according to example 19, a thickness of the liner material is less than about 10% of a width of the opening.

Example 21 provides the method according to any one of examples 19-20, in which the IC structure is an IC structure according to any one of the preceding claims.

Example 22 provides an IC package that includes an IC die including an IC structure according to any one of examples 1-18; and a further IC component, coupled to the IC die.

Example 23 provides the IC package according to example 22, where the further IC component includes a package substrate.

Example 24 provides the IC package according to example 22, where the further IC component includes an interposer.

Example 25 provides the IC package according to example 22, where the further IC component includes a further IC die.

Example 26 provides a computing structure that includes a carrier substrate and an IC structure coupled to the carrier substrate, where the IC structure is an IC structure according to any one of examples 1-18, or the IC structure is included in the IC package according to any one of claims 22-25.

Example 27 provides the computing structure according to example 26, where the computing structure is a wearable or handheld computing structure.

Example 28 provides the computing structure according to examples 26 or 27, where the computing structure further includes one or more communication chips.

Example 29 provides the computing structure according to any one of examples 26-28, where the computing structure further includes an antenna.

Example 30 provides the computing structure according to any one of examples 26-29, where the carrier substrate is a motherboard.

Example 31 provides the IC structure according to any one of examples 1-18, in which the IC structure includes or is a part of a central processing unit.

Example 32 provides the IC structure according to any one of examples 1-31, in which the IC structure includes or is a part of a memory structure.

Example 33 provides the IC structure according to any one of examples 1-32, in which the IC structure includes or is a part of a logic circuit.

Example 34 provides the IC structure according to any one of examples 1-33, in which the IC structure includes or is a part of input/output circuitry.

Example 35 provides the IC structure according to any one of examples 1-34, in which the IC structure includes or is a part of a field programmable gate array transceiver.

Example 36 provides the IC structure according to any one of examples 1-35, in which the IC structure includes or is a part of a field programmable gate array logic.

Example 37 provides the IC structure according to any one of examples 1-36, in which the IC structure includes or is a part of a power delivery circuitry.

Example 38 provides the IC structure according to any one of examples 1-37, in which the IC structure includes or is a part of a III-V amplifier.

Example 39 provides the IC structure according to any one of examples 1-38, in which the IC structure includes or is a part of Peripheral Component Interconnect Express circuitry or Double Data Rate transfer circuitry.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a channel region of a transistor;
a first region proximate to a first end of the channel region; and
a second region proximate to a second end of the channel region, wherein one of the first region and the second region is a source region of the transistor and another one of the first region and the second region is a drain region of the transistor,
wherein:
the first region includes a liner material and a fill material,
the liner material is laterally between the fill material and the channel region, and
a material composition of the liner material is different from a material composition of the fill material.

2. The IC structure according to claim 1, wherein the liner material includes silicon and boron.

3. The IC structure according to claim 2, wherein the liner material further includes germanium.

4. The IC structure according to claim 2, wherein atomic percentage of germanium in the liner material is less than about 5 percent.

5. The IC structure according to claim 1, wherein the liner material includes silicon and germanium.

6. The IC structure according to claim 1, wherein:
the first region includes an opening in a semiconductor material of the channel region,
the liner material lines sidewalls and bottom of the opening, and
the fill material at least partially filles the opening lined with the liner material.

7. The IC structure according to claim 6, wherein a thickness of the liner material is less than about 10% of a width of the opening.

8. The IC structure according to claim 1, wherein a thickness of the liner material is between about 1 nanometer and 10 nanometers.

9. The IC structure according to claim 1, wherein a thickness of the liner material is below about 3 nanometers.

10. The IC structure according to claim 1, wherein the liner material is etch-selective with respect to a material of the channel region.

11. An integrated circuit (IC) structure, comprising:
a first transistor; and
a second transistor,
wherein:
an individual one of the first transistor and a second transistor includes a channel region, and a region proximate to an end of the channel region, wherein the region is a source region or a drain region,
the region of the first transistor includes a first liner material and a first fill material,
the region of the second transistor includes a second liner material and a second fill material,
the first liner material includes silicon and boron, and
the second liner material includes silicon and germanium.

12. The IC structure according to claim 11, wherein the first liner material further includes germanium.

13. The IC structure according to claim 12, wherein atomic percentage of germanium in the first liner material is less than about 5 percent.

14. The IC structure according to claim 11, wherein:
the first liner material is between the first fill material and the channel region of the first transistor, or
the second liner material is between the second fill material and the channel region of the second transistor.

15. The IC structure according to claim 11, wherein:
a material composition of the first liner material is different from a material composition of the first fill material, or
a material composition of the second liner material is different from a material composition of the second fill material.

16. The IC structure according to claim 11, wherein:
a material composition of the first liner material is different from a material composition of the second liner material.

17. The IC structure according to claim 11, wherein a thickness of the first liner material is between about 1 nanometer and 10 nanometers.

18. The IC structure according to claim 11, wherein a thickness of the second liner material is between about 1 nanometer and 10 nanometers.

19. A method of fabricating an integrated circuit (IC) structure, the method comprising:
forming an opening for a region of a transistor, wherein the region is either a source region or a drain region;
depositing a liner material on sidewalls of the opening; and
depositing a fill material in the opening with the liner material,
wherein:
the liner material includes silicon and boron if the transistor is a P-type transistor,
the liner material includes silicon and germanium if the transistor is an N-type transistor, and
a material composition of the liner material is different from a material composition of the fill material.

20. The method according to claim 19, a thickness of the liner material is less than about 10% of a width of the opening.
